(19) United States
(12) Patent Application Publication
(10) Pub. No.: US 2013/0115737 A1
(43) Pub. Date: May 9, 2013

(54) METHOD OF MANUFACTURING A SEMICONDUCTOR DEVICE WITH OUTER LEADS HAVING A LEAD-FREE PLATING

(71) Applicant: Renesas Electronics Corporation, Kanagawa (JP)

(72) Inventor: Tomohiro MURAKAMI, Kawasaki-shi (JP)

(73) Assignee: Renesas Electronics Corporation, Kanagawa (JP)

(21) Appl. No.: 13/730,200

(22) Filed: Dec. 28, 2012

Related U.S. Application Data
(62) Division of application No. 12/779,527, filed on May 13, 2010.

(30) Foreign Application Priority Data
Jun. 8, 2009 (JP) 2009-137654

(51) Int. Cl. H01L 23/00

(52) U.S. Cl. CPC H01L 24/89
USPC 438/123

(57) ABSTRACT

A semiconductor device has a tab having a semiconductor chip fixed thereto, a plurality of inner leads, a plurality of outer leads formed integrally with the inner leads, a plurality of wires coupling the electrode pads of the semiconductor chip to the inner leads, and a molded body having the semiconductor chip molded therein. Over a surface of each of the outer leads protruding from the molded body, an outer plating including lead-free platings is formed. The outer plating has, in a thickness direction thereof, a first lead-free plating and a second lead-free plating, the first and second lead-free platings having the same composition and meeting at an interface. The first and second lead-free platings are formed under different conditions and may have different physical properties.

### CROSS-REFERENCE TO RELATED APPLICATIONS

This is a Divisional of U.S. patent application Ser. No. 12/779,527, filed May 13, 2010, now abandoned. This application also claims priority to Japanese Patent Application No. 2009-137654 filed on Jun. 8, 2009. The contents of the aforementioned applications are incorporated by reference in their entirety.

### BACKGROUND OF THE INVENTION

The present invention relates to a semiconductor device and a manufacturing technology therefor, and particularly to a technology which is effective at improving resistance to whisker formation over lead-free plating.

There is described a structure wherein, in a semiconductor integrated circuit device, an alloy layer which has a melting point higher than that of a tin-lead eutectic solder, and does not contain lead as a main constituent metal thereof is provided in a portion outside a portion molded with a resin, as discussed in Japanese Unexamined Patent Publication No. 2006-352175.

### SUMMARY OF THE INVENTION

A process of assembling a semiconductor device using a lead frame primarily includes a die bonding step of mounting a semiconductor chip over a die pad over the lead frame, a wire bonding step of electrically coupling the electrode pads of the semiconductor chip to inner leads, a packaging (molding) step of molding the semiconductor chip and wires, and a singulation step of cutting/separating outer leads from the lead frame.

The assembling process further includes, after the packaging step and prior to the singulation step, an outer plating step of performing an outer plating process with respect to each of the outer leads. In the outer plating step, an outer plating is formed over each of the outer leads exposed from a molded body to attach the semiconductor device to a mounting substrate such as a printed board.

In recent years, a solution to an environmental problem has been required, and therefore a lead-free plating which does not use lead has been mostly used as the outer plating. Examples of the mostly used lead-free plating include a tin-copper plating, a tin-bismuth plating, a tin-silver plating, and a pure tin plating.

However, when a temperature cycle test is performed in a process of inspecting the semiconductor device, a whisker-shaped metal crystal product called “whisker” may be formed over the surface of the outer lead.

The mechanism of whisker formation in the temperature cycle test is considered to be such that, since the base material (e.g., an iron-nickel alloy) of the outer lead and a lead-free plating (e.g., a tin-copper plating) have different linear expansion coefficients, a distortion occurs due to the thermocompression of the outer lead and the lead-free plating caused by a temperature cycle, and is gradually accumulated in the lead-free plating to finally protrude to the outside as the whisker.

When the whisker is thus formed over the outer lead of the semiconductor device, an electric short-circuit occurs in the semiconductor device to present a problem.

In the case of the structure described in Japanese Unexamined Patent Publication No. 2006-352175 mentioned above, the outer plating over the surface of each of the outer leads is formed of only one type of plating, and an interface is not formed in the outer plating. Accordingly, a stress (distortion) occurring in the temperature cycle test has a rather high probability of being propagated without being reduced, and forming the whisker.

The present invention has been achieved in view of the foregoing problem, and an object of the present invention is to provide a technology which can achieve an improvement in resistance to whisker formation.

The above and other objects and novel features of the present invention will become apparent from a description in the present specification and the accompanying drawings.

The following is a brief description of the outline of representative aspects of the invention disclosed in the present application.

That is, an aspect of the present invention is a semiconductor device, including: a semiconductor chip provided with a plurality of surface electrodes; a die pad having the semiconductor chip mounted thereon; a plurality of inner leads arranged around the semiconductor chip; a plurality of wires electrically coupling the surface electrodes of the semiconductor chip to the respective inner leads; a molded body having the semiconductor chip, the inner leads, and the wires each molded therein; a plurality of outer leads integrally coupled to the respective inner leads, and exposed from the molded body; and an outer plating formed over a surface of each of the outer leads, wherein the outer plating has a first lead-free plating formed under a desired condition, and a second lead-free plating having a composition of the same system as that of a composition of the first lead-free plating, and wherein the first lead-free plating and the second lead-free plating are laminated.

That is, another aspect of the present invention is a method of manufacturing a semiconductor device, including the steps of: (a) preparing a lead frame formed with a molded body covering a semiconductor chip; and (b) placing the lead frame in a plating apparatus including a first plating unit and a second plating unit which are individually coupled to different rectifiers, and performing a lead-free plating process with respect to a plurality of outer leads exposed from the molded body of the lead frame, wherein, in the step (b), a first current density is applied in the first plating unit with the lead frame being dipped in a first lead-free plating solution to perform a first lead-free plating process with respect to the outer leads, and then a second current density at a density different from a density of the first current density is applied in the second plating unit with the lead frame being dipped in a second lead-free plating solution having a composition of the same system as that of a composition of the first lead-free plating solution to perform a second lead-free plating process with respect to the outer leads.

That is, still another aspect of the present invention is a method of manufacturing a semiconductor device, including the steps of: (a) preparing a thin-plate-like lead frame having a die pad, a plurality of inner leads arranged around the die pad, and a plurality of outer leads integrally coupled to the respective inner leads; (b) mounting a semiconductor chip over the die pad; (c) electrically coupling a plurality of electrode pads of the semiconductor chip to the respective inner leads with wires; (d) molding the semiconductor chip, the inner leads, and the wires into a molded body; (e) placing the lead frame formed with the molded body in a plating apparatus including a first plating unit and a second plating unit which are individually coupled to different rectifiers, and performing a lead-free plating process with respect to the outer leads exposed from the molded body; and (f) cutting/separating the outer leads from the lead frame to perform singulation, wherein, in the step (e), a first current density is applied in the first plating unit with the lead frame being dipped in a first lead-free plating solution to perform a first lead-free plating process with respect to the outer leads, and then a second current density at a density different from a density of the first current density is applied in the second plating unit with the lead frame being dipped in a second lead-free plating solution having a composition of the same system as that of a composition of the first lead-free plating solution to perform a second lead-free plating process with respect to the outer leads.

The following is a brief description of effects achievable by the representative aspects of the invention disclosed in the present application.

Even when a stress occurs between the outer lead and the outer plating in a temperature cycle test, the propagation of the stress can be reduced using an interface formed between the first lead-free plating and the second lead-free plating which are included in the outer plating. As a result, it is possible to reduce the potential of whisker formation, and improve resistance to whisker formation.

### BRIEF DESCRIPTION OF THE DRAWINGS

FIG. 1 is a plan view showing an example of a structure of a semiconductor device assembled by a method of manufacturing a semiconductor device according to Embodiment 1 of the present invention;

FIG. 2 is a cross-sectional view showing a structure resulting from cutting along the line A-A shown in FIG. 1;

FIG. 3 is a partial cross-sectional view showing an example of a plating structure at the portion A shown in FIG. 2;

FIG. 4 is an enlarged partial cross-sectional view showing an example of a detailed structure of an outer plating at the portion B shown in FIG. 3;

FIG. 5 is an enlarged partial cross-sectional view showing a detailed structure of an outer plating according to a first variation at the portion B shown in FIG. 3;

FIG. 6 is an enlarged partial cross-sectional view showing a detailed structure of an outer plating according to a second variation at the portion B shown in FIG. 3;

FIG. 7 is a manufacturing flow chart showing an example of the procedure of assembling the semiconductor device shown in FIG. 1;

FIG. 8 is an enlarged partial plan view showing an example of a structure of a lead frame used in the assembly of the semiconductor device shown in FIG. 1;

FIG. 9 is a partial cross-sectional view showing an example of a structure after die bonding in the assembly of the semiconductor device shown in FIG. 1;

FIG. 10 is a partial cross-sectional view showing an example of a structure after wire bonding in the assembly of the semiconductor device shown in FIG. 1;

FIG. 11 is a partial cross-sectional view showing an example of a structure after resin molding in the assembly of the semiconductor device shown in FIG. 1;

FIG. 12 is a partial cross-sectional view showing an example of a structure after cutting/forming in the assembly of the semiconductor device shown in FIG. 1;

FIG. 13 is a block structural view showing an example of a structure of a plating apparatus used in a lead-free plating formation step in the assembly of the semiconductor device shown in FIG. 1;

FIG. 14 is a schematic view showing an example of a power supply method in the plating apparatus shown in FIG. 13;

FIG. 15 is a structural schematic view showing an example of a structure of a plating jig used in the power supply method shown in FIG. 14;

FIG. 16 is a plating formation specification table showing an example of solutions used in the individual processes of the lead-free plating formation step using the plating apparatus shown in FIG. 13 and the purposes of the individual processes;

FIG. 17 is a view showing an example of the result of examining a status of whisker formation when a temperature cycle test is performed with respect to lead-free platings formed using the plating apparatus shown in FIG. 13;

FIG. 18 is a block structural view showing an example of a structure of a plating apparatus used in a lead-free plating formation step in the assembly of a semiconductor device according to Embodiment 2 of the present invention;

FIG. 19 is a schematic view showing an example of a power supply method in the plating apparatus shown in FIG. 18;

FIG. 20 is a schematic structural view showing an example of a structure of a transport belt used in the power supply method shown in FIG. 19; and

FIG. 21 is a block structural view showing a structure of a variation of the plating apparatus used in the lead-free plating formation step in the assembly of the semiconductor device according to Embodiment 2.

### DESCRIPTION OF THE PREFERRED EMBODIMENTS

In the following embodiment, a description of the same or like parts will not be repeated in principle unless particularly necessary.

In the following embodiment, if necessary for the sake of convenience, the following embodiment will be described by dividing it into a plurality of sections or embodiments. However, they are by no means irrelevant to each other unless shown particularly explicitly, and are mutually related to each other such that one of the sections or embodiments is a variation or a detailed or complementary description of some or all of the others.

When the number and the like (including the number, numerical value, amount, and range thereof) of elements are referred to in the following embodiments, they are not limited to specific numbers unless shown particularly explicitly or unless they are obviously limited to specific numbers in principle. It is assumed that the number and the like of the elements may be not less than or not more than specific numbers.

It will be appreciated that, in the following embodiments, the components thereof (including also elements, steps, and the like) are not necessarily indispensable unless shown particularly explicitly or unless the components are considered to be obviously indispensable in principle.

It will also be appreciated that, when the wording “comprised of A”, “comprising”, “having A”, or “including A” is used for a component A or the like in the following embodiments, it does not exclude a component other than the component A unless it is shown particularly explicitly that the component A is the only one component. Likewise, if the shapes, positional relationship, and the like of components and the like are referred to in the following embodiments, the shapes and the like are assumed to include those substantially proximate or similar thereto unless shown particularly explicitly or unless obviously they are not in principle. The same holds true with regard to the foregoing numerical value and range.

Hereinbelow, the embodiments of the present invention will be described in detail based on the drawings. Throughout the drawings for illustrating the embodiments, members having the same functions are provided with the same reference numerals, and a repeated description thereof is omitted.

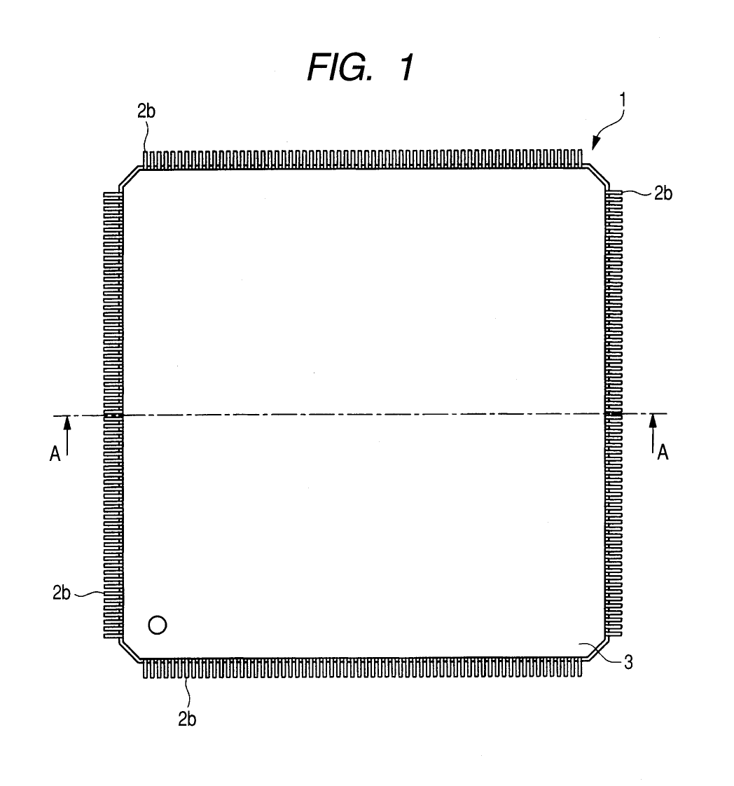

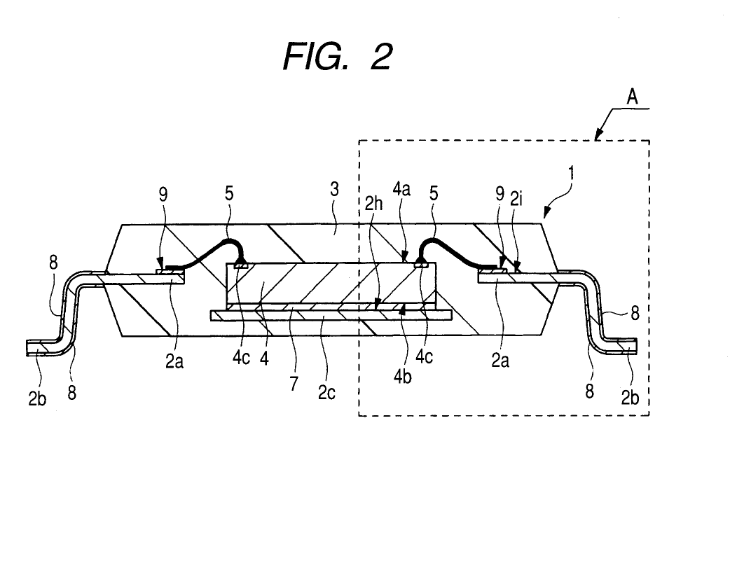

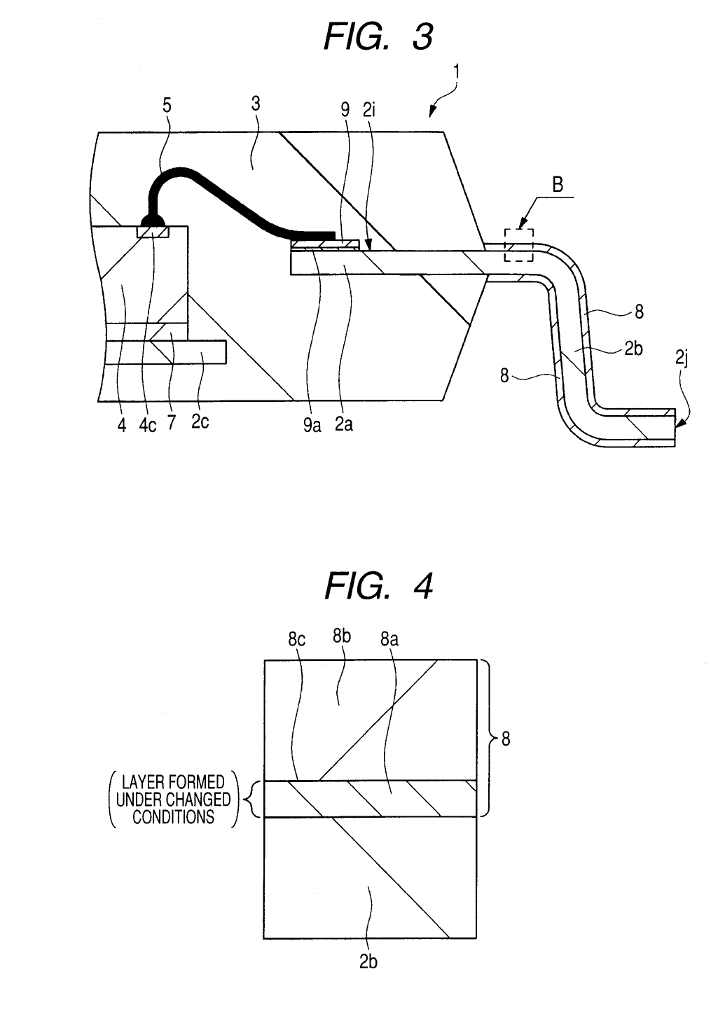

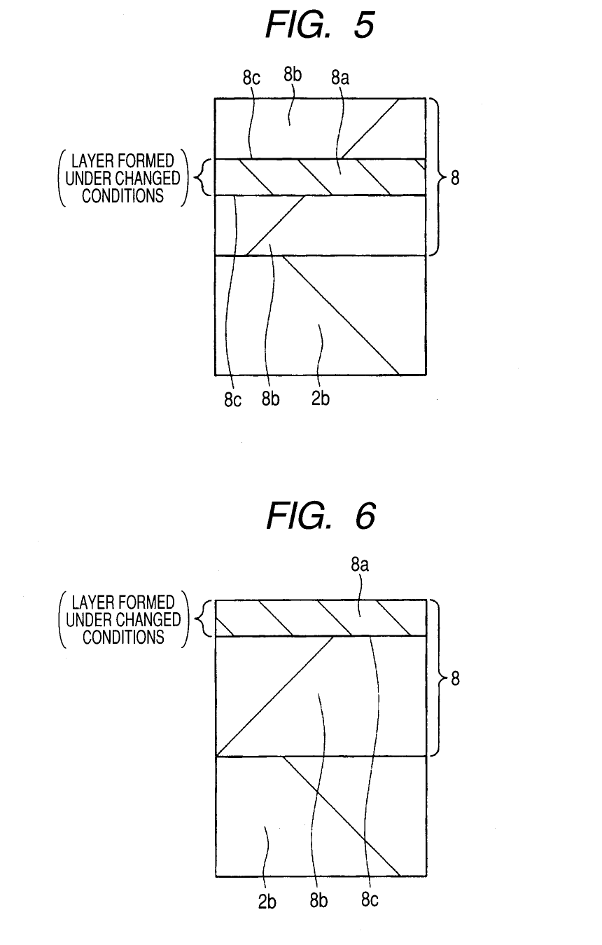

FIG. 1 is a plan view showing an example of a structure of a semiconductor device assembled by a method of manufacturing a semiconductor device according to Embodiment 1 of the present invention. FIG. 2 is a cross-sectional view showing a structure resulting from cutting along the line A-A shown in FIG. 1. FIG. 3 is a partial cross-sectional view showing an example of a plating structure at the portion A shown in FIG. 2. FIG. 4 is an enlarged partial cross-sectional view showing an example of a detailed structure of an outer plating at the portion B shown in FIG. 3. FIG. 5 is an enlarged partial cross-sectional view showing a detailed structure of an outer plating according to a first variation at the portion B shown in FIG. 3. FIG. 6 is an enlarged partial cross-sectional view showing a detailed structure of an outer plating according to a second variation at the portion B shown in FIG. 3.

The semiconductor device according to Embodiment 1 is a resin-molded semiconductor package assembled using a lead frame. In Embodiment 1, a description will be given using a multi-pin Quad Flat Package (QFP) 1 as shown in FIG. 1 as an example of the semiconductor device mentioned above.

The structure of the QFP 1 shown in FIGS. 1 and 2 will be described. The QFP 1 has a semiconductor chip 4 formed with a semiconductor integrated circuit, a plurality of inner leads 2a radially arranged around the semiconductor chip 4, a plurality of outer leads 2b formed integrally with the inner leads 2a, and a plurality of wires 5 such as gold wires which electrically couple electrode pads 4c as surface electrodes formed over the principal surface 4a of the semiconductor chip 4 and the inner leads 2a corresponding thereto.

The QFP 1 further has a tab (die pad) 2c as a chip mounting portion having the semiconductor chip 4 fixed thereto via a die bonding material 7 such as a silver paste, and a molded body 3 in which the semiconductor chip 4, the tab 2c, the plurality of wires 5, and the plurality of inner leads 2a are molded. Because the semiconductor device according to Embodiment 1 is the QFP 1, the plurality of outer leads 2b formed integrally with the plurality of respective inner leads 2a protrude from each of the four sides of the molded body 3 toward the outside, and each of the outer leads 2b is formed into a gull-wing shape by bending.

In the semiconductor chip 4 mounted over the QFP 1, the plurality of electrode pads 4c formed over the principal surface 4a thereof are provided with a narrow pad pitch of not more than 50 μm. This allows gold wires each having a wire diameter of, e.g., not more than 20 μm to be adopted as the wires 5, and also allows a multi-pin configuration to be implemented.

The inner leads 2a, the outer leads 2b, and the tab 2c are each formed of a thin-plate-like member of an iron-nickel alloy, a copper alloy, or the like. The molded body 3 is made of, e.g., a thermosetting epoxy resin or the like, and formed by resin molding.

The semiconductor chip 4 is formed of, e.g., silicon or the like. Over the principal surface 4a of the semiconductor chip 4, the semiconductor integrated circuit is formed, and the semiconductor chip 4 is fixed onto the principal surface 2h of the tab 2c with the die bonding material 7. That is, the back surface 4b of the semiconductor chip 4 and the principal surface 2h of the tab 2c are bonded to each other via the die bonding material 7.

As shown in FIG. 3, over the wire bonded portion 2i of each of the plurality of inner leads 2a in the vicinity of the end portion thereof, a silver plating 9 is formed to enhance the reliability of coupling with the wire 5 such as a gold wire. The silver plating 9 is formed over a base copper plating 9a formed over the surface of each of the inner leads 2a.

Here, in the QFP 1 according to Embodiment 1, an outer plating 8 including lead-free platings is formed over the surface of each of the plurality of outer leads 2b protruding from the molded body 3, as shown in FIG. 2. As shown in FIGS. 3 and 4, the outer plating 8 has a first lead-free plating 8a (lead-free plating against whisker formation or layer formed under changed conditions) formed under desired conditions, and a second lead-free plating 8b (typical lead-free plating) having a composition of the same system as that of the composition of the first lead-free plating 8a. The first lead-free plating 8a and the second lead-free plating 8b are laminated. That is, over each of the outer leads 2b, the two types of lead-free platings formed under different plating conditions are laminated, and formed as the outer plating 8.

Note that, as shown in FIG. 3, the cut surface 2j at the tip portion of each of the outer leads 2b is a surface formed as a result of cutting the lead after the formation of the plating, and therefore the outer plating 8 is not formed thereover.

Note that the first lead-free plating 8a and the second lead-free plating 8b may be lead-free platings having respective compositions of the same system, or lead-free platings having different compositions. Each of the first lead-free plating 8a and the second lead-free plating 8b may be any of, e.g., a tin (Sn)-copper (Cu) plating, a tin (Sn)-silver (Ag) plating, a tin (Sn)-bismuth (Bi) plating, a pure tin (Sn) plating, and the like among various lead-free platings. However, each of the first lead-free plating 8a and the second lead-free plating 8b is preferably the same lead-free plating. Here, a description will be given using, as an example, the case where each of the first lead-free plating 8a and the second lead-free plating 8b is a tin-copper plating.

That is, in the case where each of the first lead-free plating 8a and the second lead-free plating 8b is the same tin-copper plating, the first lead-free plating 8a and the second lead-free plating 8b are formed by applying respective currents at different densities when the first lead-free plating 8a and the second lead-free plating 8b are formed in the step of forming the outer plating 8 in the QFP 1 according to Embodiment 1. In other words, even though each of the first lead-free plating 8a and the second lead-free plating 8b is the same tin-copper plating, the first lead-free plating 8a and the second lead-free plating 8b are formed under different plating conditions such as the densities of the applied currents.

For example, in the outer plating 8 shown in FIG. 4, a desired first current density is applied as a first plating process (first-stage plating process) to form the first lead-free plating 8a over the surface of each of the outer leads 2b, and then a second current density at a density different from that of the foregoing first current density is applied as a second plating process (second-stage plating process) to form the second lead-free plating 8b in laminated relation over the first lead-free plating 8a, thereby implementing a double-layered outer plating structure. By repeatedly performing the second plating process a plurality of times, the second lead-free plating 8b is formed thicker than the first lead-free plating 8a.

For example, the desired first current density is applied as the first plating process to form the first lead-free plating 8a over the surface of each of the outer leads 2b, and then the second current density at a density lower than that of the foregoing first current density is applied as the second plating process to form the second lead-free plating 8b over the first lead-free plating 8a.

That is, the first lead-free plating 8a formed directly over the surface of the outer lead 2b of FIG. 4 is a plating formed with the current at a density higher than that of the current for the second lead-free plating 8b formed over the first lead-free plating 8a. As a result, the first lead-free plating 8a is formed over the surface of the outer lead 2b, and the second lead-free plating 8b is further formed over the first lead-free plating 8a. In other words, the first lead-free plating 8a is disposed closer to the lead in the thickness direction of the outer plating 8.

Consequently, in the outer plating 8a, an interface 8c is formed on the boundary between the first lead-free plating 8a and the second lead-free plating 8b. That is, by using the respective currents at different densities (different plating conditions) during the formation of the first lead-free plating 8a and the second lead-free plating 8b, a lead-free plating film including the two layers having different physical properties is formed in the outer plating 8, and the interface 8c is formed therein. The two platings 8a, 8b may exhibit different physical properties even though they have the same composition. One example of a physical property that may differ in the two platings is the crystalline structure. In a finished outer lead, one may distinguish between the two platings by examining their crystalline structure, such as by spectroscopy.

Thus, in the outer plating 8, the interface 8c is formed between the first lead-free plating 8a and the second lead-free plating 8b. Therefore, even when a stress occurs between the outer lead 2b and the outer plating 8 in a temperature cycle test, it is possible to reduce the propagation of the stress using the interface 8c formed in the outer plating 8.

As a result, it is possible to reduce the potential of whisker formation, and improve resistance to whisker formation.

Note that the linear expansion coefficient of tin is, e.g., 23 ppm, the linear expansion coefficient of copper is, e.g., 17 ppm, and the linear expansion coefficient of an iron-nickel alloy is, e.g., 5 ppm. As a result, there is a linear expansion coefficient difference of 18 ppm between tin and the iron-nickel alloy so that, when a temperature change occurs, a distortion (stress) increases. However, in the QFP 1 according to Embodiment 1, the interface 8c is formed between the first lead-free plating 8a and the second lead-free plating 8b in the outer plating 8. Therefore, it is possible to inhibit the propagation of the distortion (stress) using the interface 8c, reduce the potential of whisker formation, and achieve an improvement in resistance to whisker formation. Note that, between tin and copper, there is a linear expansion coefficient difference of 6 ppm but, because the difference is relatively small, the distortion (stress) is small even when a temperature change occurs so that whisker is not formed.

Next, a first variation shown in FIG. 5 and a second variation shown in FIG. 6 will be described.

FIG. 5 shows a plating structure in which, in the outer plating 8 formed over the outer lead 2b, the first lead-free plating 8a (lead-free plating against whisker formation or layer formed under changed conditions) is interposed between the second lead-free platings 8b (typical lead-free platings).

That is, in the outer plating 8, the first lead-free plating 8a is disposed in interposed relation between the second lead-free platings 8b in the thickness direction of the outer plating 8. The plating structure is obtained by applying the desired second current density as the first plating process (first-stage plating process) to form the second lead-free plating 8b over the surface of the outer lead 2b, then applying the first current density at a density different from that of the foregoing second current density as the second plating process (second-stage plating process) to form the first lead-free plating 8a over the second lead-free plating 8b, and further applying the foregoing second current density as a third plating process (third-stage plating process) to form the second lead-free plating 8b over the first lead-free plating 8a in the outer plating formation step. By thus performing plating formation at three stages, it is possible to implement a triple-layered outer plating structure in which the first lead-free plating 8a is interposed between the second lead-free platings 8b as shown in FIG. 5.

FIG. 6 shows a plating structure in which, in the outer plating 8 formed over the outer lead 2b, the first lead-free plating 8a (lead-free plating against whisker formation) is disposed closer to the surface of the outer plating 8 in the thickness direction thereof.

That is, in the outer plating 8, the second lead-free plating 8b is formed over the outer lead 2b, and the first lead-free plating 8a (lead-free plating against whisker formation) is further disposed over the second lead-free plating 8b. The plating structure is obtained by applying the desired second current density as the first plating process (first-stage plating process) to form the second lead-free plating 8b over the surface of the outer lead 2b, and then applying the first current density at a density different from that of the foregoing second current density as the second plating process (second-stage plating process) to form the first lead-free plating 8a over the second lead-free plating 8b in the outer plating formation step. In this manner, the double-layered outer plating structure can be implemented.

Note that, by repeatedly performing the first plating process a plurality of times, the second lead-free plating 8b can be formed thicker than the first lead-free plating 8a.

In the structure of the outer plating 8 shown in FIGS. 5 and 6 also, the interface 8c is formed between the first lead-free plating 8a and the second lead-free plating 8b in the inside thereof. Therefore, even when a stress occurs between the outer lead 2b and the outer plating 8 in a temperature cycle test, the propagation of the stress can be reduced using the interface 8c. As a result, it is possible to reduce the potential of whisker formation, and improve resistance to whisker formation.

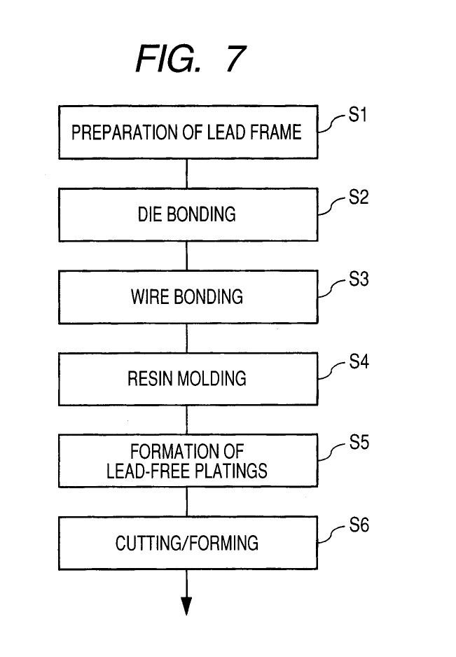

Next, a method of manufacturing the semiconductor device (QFP1) according to Embodiment 1 will be described in accordance with the manufacturing flow chart shown in FIG. 7.

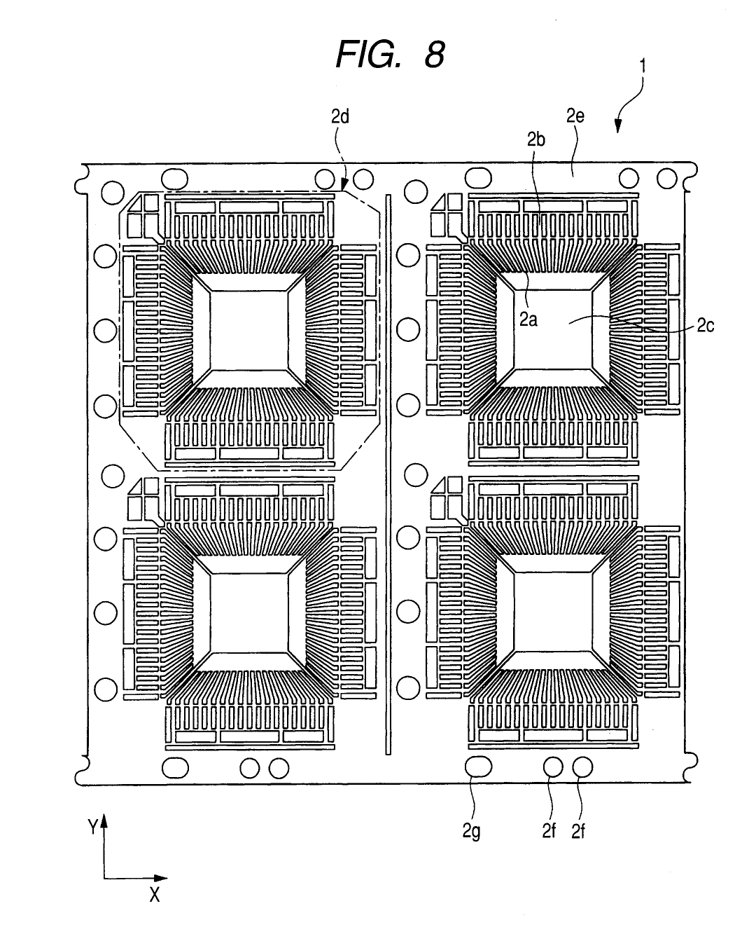

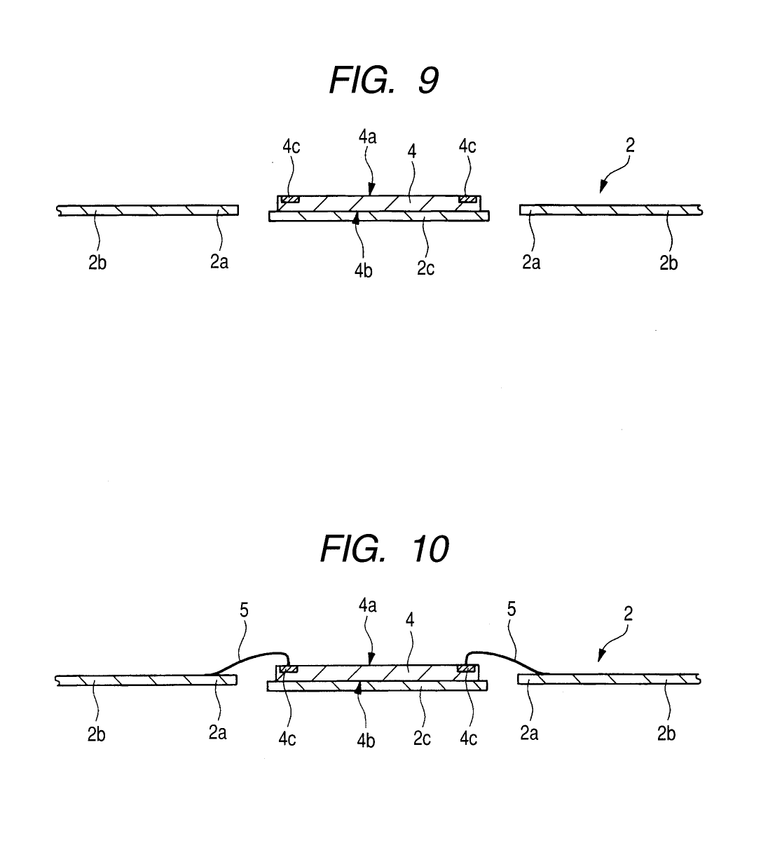

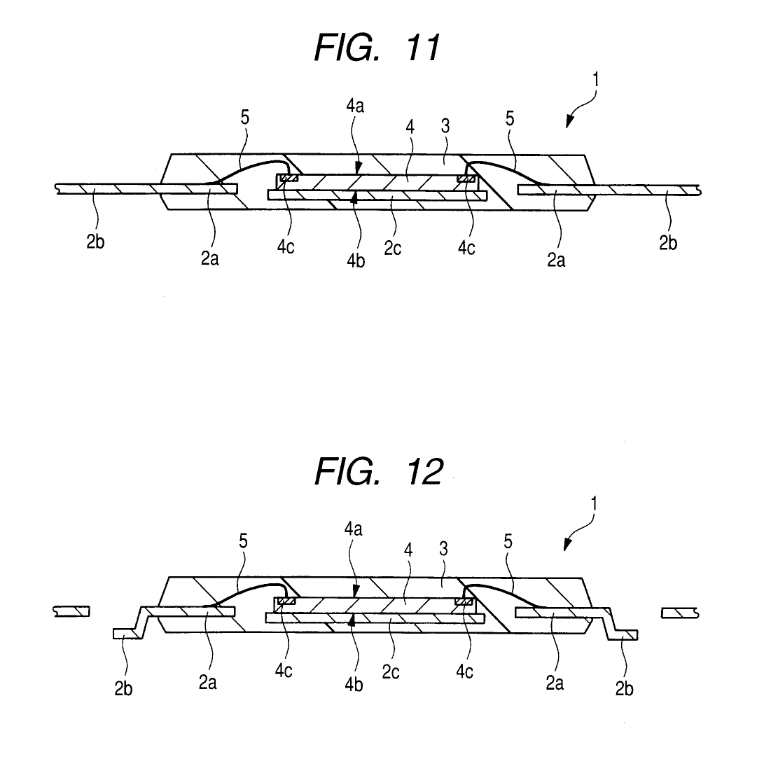

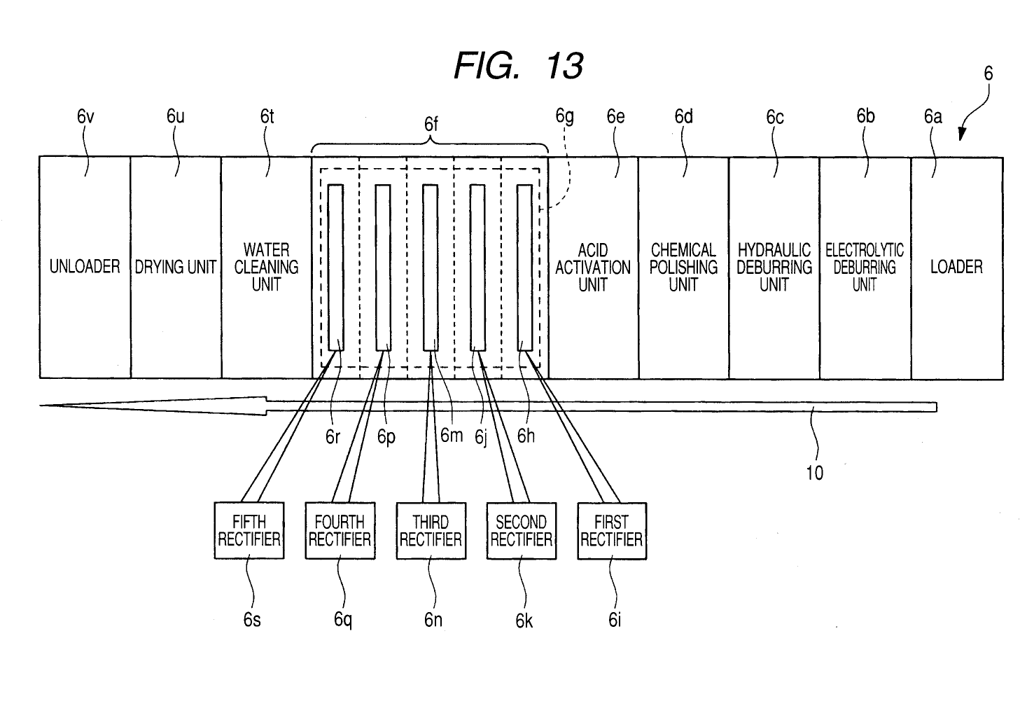

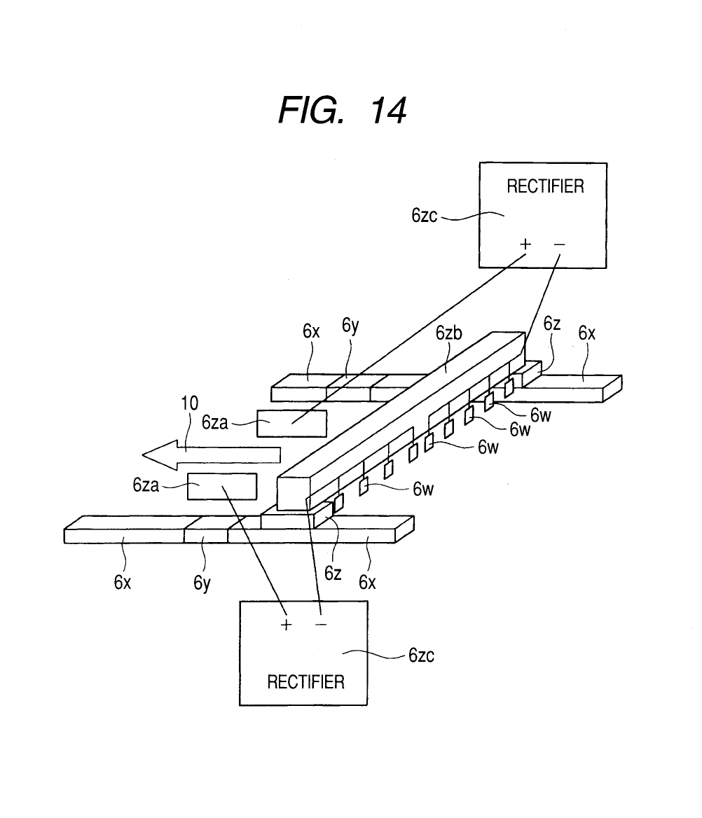

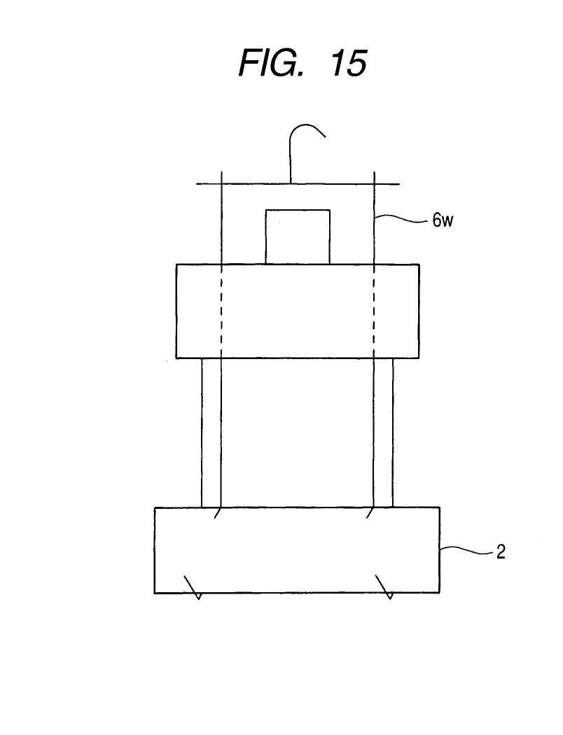

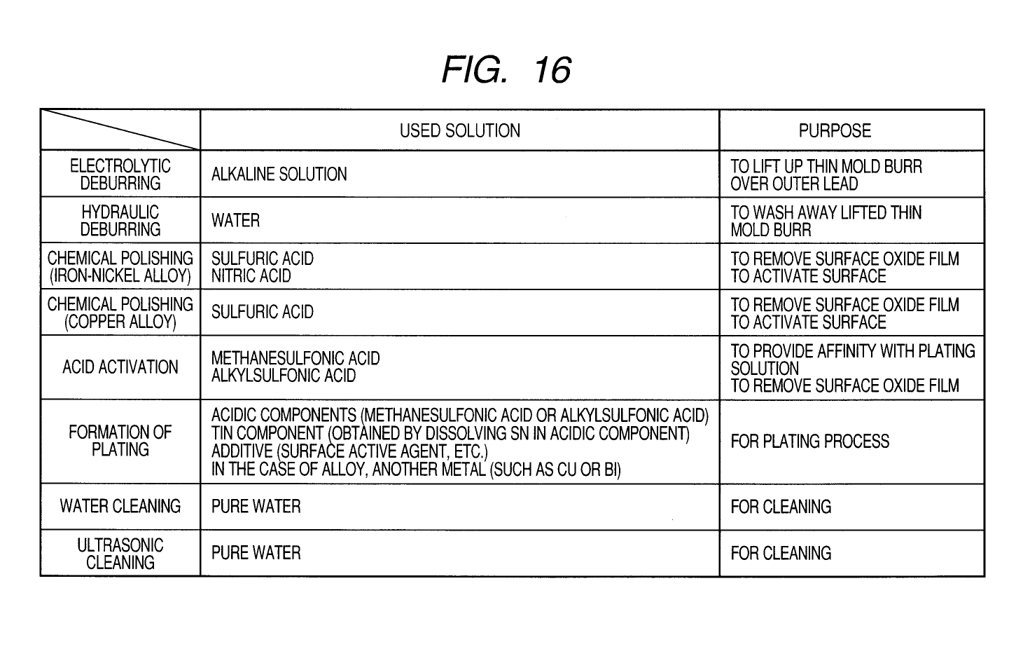

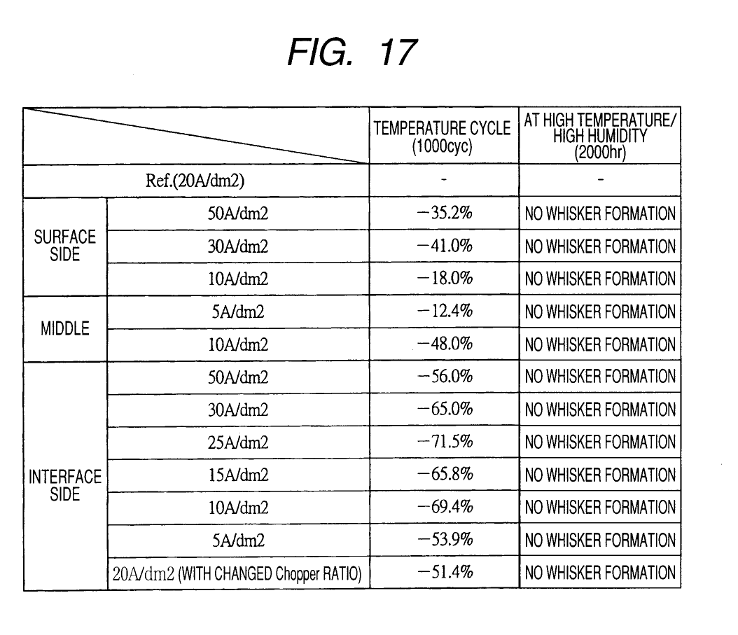

FIG. 7 is the manufacturing flow chart showing an example of the procedure of assembling the semiconductor device shown in FIG. 1. FIG. 8 is an enlarged partial plan view showing an example of a structure of a lead frame used in the assembly of the semiconductor device shown in FIG. 1. FIG. 9 is a partial cross-sectional view showing an example of a structure after die bonding in the assembly of the semiconductor device shown in FIG. 1. FIG. 10 is a partial cross-sectional view showing an example of a structure after wire bonding in the assembly of the semiconductor device shown in FIG. 1. FIG. 11 is a partial cross-sectional view showing an example of a structure after resin molding in the assembly of the semiconductor device shown in FIG. 1. FIG. 12 is a partial cross-sectional view showing an example of a structure after cutting/forming in the assembly of the semiconductor device shown in FIG. 1. FIG. 13 is a block structural view showing an example of a structure of a plating apparatus used in a lead-free plating formation step in the assembly of the semiconductor device shown in FIG. 1. FIG. 14 is a schematic view showing an example of a power supply method in the plating apparatus shown in FIG. 13. FIG. 15 is a structural schematic view showing an example of a structure of a plating jig used in the power supply method shown in FIG. 14. FIG. 16 is a plating formation specification table showing an example of solutions used in the individual processes of the lead-free plating formation step using the plating apparatus shown in FIG. 13 and the purposes of the individual processes. FIG. 17 is a view showing an example of the result of examining a status of whisker formation when a temperature cycle test is performed with respect to lead-free platings formed using the plating apparatus shown in FIG. 13.

First, the preparation of the lead frame shown in Step S1 of FIG. 7 is performed. Here, a matrix frame 2 as an example of the lead frame shown in FIG. 8 is prepared. In the matrix frame 2, a plurality of device regions 2d over each of which the semiconductor chip 4 is to be mounted are formed in an arrangement. In each of the device regions 2d, the plurality inner leads 2a and outer leads 2b are provided.

In the matrix frame 2 shown in FIG. 8 which is used in Embodiment 1, the device regions 2d each as a region for forming the one QFP1 are formed in a matrix arrangement including a plurality of rows and columns (e.g., two rows and two columns in FIG. 8). In each of the device regions 2d, the one tab (die pad) 2c, the plurality of inner leads 2a and outer leads 2b arranged around the tab 2c, and the like are formed.

The matrix frame 2 is a rectangular thin-plate member formed of, e.g., an iron-nickel alloy, a copper alloy, or the like. The tab 2c, the plurality of inner leads 2a and outer leads 2b are formed in integrally coupled relation. In the matrix 2 shown in FIG. 8, the X-direction is the lengthwise direction of a rectangle, and the Y-direction is the widthwise direction of the rectangle.

In the frame portions 2e of the matrix frame 2 at the both widthwise end portions thereof, a plurality of oblong holes 2g for alignment and a plurality of sprocket holes 2f for guiding which are used at the time of processing are provided.

The number of the inner leads 2a in one of the device regions 2d in the matrix frame 2 shown in FIG. 8 is different from the number of the outer leads 2b in the QFP1 shown in FIG. 1. However, this is for clear illustration of the shape of the lead portion of the matrix frame 2. It will be appreciated that the number of the inner leads 2a in one of the device regions 2d in the matrix frame 2 used to assemble the QFP1 is the same as the number of the outer leads 2b in the QFP1.

Thereafter, the die bonding shown in Step S2 of FIG. 7 is performed. Here, over the tab 2c of each of the plurality of device regions 2d of the matrix frame 2, the semiconductor chip 4 is mounted via the die bonding material 7, as shown in FIG. 9. That is, as shown in FIG. 2, the back surface 4b of the semiconductor chip 4 and the principal surface 2h of the tab 2c are bonded to each other with the die bonding material 7.

Thereafter, the wire bonding shown in Step S3 of FIG. 7 is performed. That is, as shown in FIG. 10, the electrode pads 4c over the principal surface 4a of the semiconductor chip 4 and the plurality of inner leads 2a corresponding thereto are electrically coupled to each other with the wires 5. For example, the wires 5 are gold wires.

After the wire bonding, the resin molding shown in Step S4 of FIG. 7 is performed. Here, the tabs 2c, the semiconductor chips 4, the plurality of inner leads 2a, and the plurality of wires 5 in the device regions 2d, which are shown in FIG. 11, are resin molded using a molding resin and a resin mold die not shown to form the molded body 3. For example, the molding resin mentioned above is a thermosetting epoxy resin or the like.

Thereafter, the formation of lead-free platings shown in Step S5 of FIG. 7 is performed. Here, the matrix frame (lead fame) 2 formed with the molded body 3 is placed in the plating apparatus 6 shown in FIG. 13 including the first plating unit and the second unit which are individually coupled to different rectifiers, and a lead-free plating process is performed with respect to the plurality of outer leads 2b exposed from the molded body 3.

Here, a description will be given of the plating apparatus shown in FIG. 13 which is used in the lead-free plating formation step of Step S5.

First, structures of the principal processing units of the plating apparatus 6 will be described. The plating apparatus 6 includes a loader 6a for placing the matrix frame 2 after the resin molding at a predetermined position, an electrolytic deburring unit 6b for performing electrical deburring, a hydraulic deburring unit 6c for performing deburring using a hydraulic pressure, a chemical polishing unit 6d for performing chemical polishing, an acid activation unit 6e for providing affinity with an acid in a plating solution, a plating formation unit 6f for forming lead-free platings, a water cleaning unit 6t for performing cleaning with water after the formation of the plating, a drying unit 6u for performing drying after the cleaning with water, and an unloader 6v for retrieving the matrix frame 2 from the predetermined position.

Note that, in the plating formation unit 6f of the plating apparatus 6 according to Embodiment 1, five stages (plating units) are disposed, and placed in the same plating vessel 6g. In other words, the five stages for the plating processes are placed in the one plating vessel 6g. To the individual stages, respective rectifiers are further electrically coupled. The number of the stages for the plating processes need not necessarily be five as long as a plurality of stages are placed. It is also possible that independent stages at which current densities can be changed may be disposed at desired positions.

In an example, as shown in FIG. 13, the one plating vessel 6g is provided in the plating formation unit 6f and, in the plating vessel 6g, a first stage (first plating unit) 6h, a second stage (second plating unit) 6j, a third stage (second plating unit) 6m, a fourth stage (second plating unit) 6p, and a fifth stage (second plating unit) 6r are placed. Further, a first rectifier 6i, a second rectifier 6k, a third rectifier 6n, a fourth rectifier 6q, and a fifth rectifier 6s are coupled respectively to the first stage 6h, the second stage 6j, the third stage 6m, the fourth stage 6p, and the fifth stage 6r, thereby allowing the application of currents at densities different from one stage to another.

That is, in the plating apparatus 6 according to Embodiment 1, lead-free platings can be formed under two different conditions in the first plating unit (first stage 6h) and in the second plating unit (second, third, fourth, and fifth stages 6j, 6m, 6p, and 6r).

Since the five stages (first and second plating units) are placed in the one plating vessel 6g, a first lead-free plating solution used in the first plating unit and a second lead-free plating solution used in the second plating unit are the same.

Note that the grouping of the stages with regard to the first plating unit and the second plating unit may be such that each of the stages may belong to either of the plating units. For example, the first stage 6h may belong to the second plating unit, or the second stage 6j may belong to the first plating unit.

Note that, in the plating formation unit 6f of the plating apparatus 6 according to Embodiment 1, the formation of a lead-free plating is performed first in the first plating unit under desired conditions, and then the formation of a lead-free plating is performed in the second plating unit under other conditions different from the desired conditions mentioned above.

In the plating apparatus 6, the matrix frames 2 after the completion of the resin molding are allowed to flow along the frame transportation direction 10 of FIG. 13, while being held by plating jigs 6w shown in FIG. 15. At that time, as shown in FIG. 14, the plurality of plating jigs 6w each being suspended from a bar member 6zb, and held thereby are guided by power supply rails 6x via jig contacts 6z so that plating processes are performed in the individual plating units. During the plating processes, power is supplied from a rectifier 6zc electrically coupled to anodes 6za to the matrix frames 2 held by the plating jigs 6w. That is, a current outputted from the rectifier 6zc is supplied to the matrix frames 2 via the power supply rails 6x/jig contacts 6z and through the wires of the plating jigs 6w.

Note that, in each of the processing units of the plating apparatus 6, in the step in which power need not be supplied to the matrix frames 2, the jig contacts 6z are placed over non-conductive rails 6y. At that time, power is not supplied to the matrix frames 2.

FIG. 17 shows the result of examining the decrease ratio (%) of the length of whisker and a status of whisker formation when the first lead-free plating 8a (layer formed under changed conditions) is formed on the lead side (inner side) of FIG. 4, at the middle of FIG. 5, and on the surface side of FIG. 6 in the outer plating 8 over the outer lead 2b shown in FIGS. 4 to 6. In the evaluation of FIG. 17, the decrease ratio (%) of the length of whisker is calculated at each of the positions and at each of the current densities using the length of whisker when the current density is 20 A/dm² as a reference.

As can be seen from FIG. 17, it has been found that a combination of an increased speed (current density) of film deposition of the lead-free plating in the first plating unit and a reduced speed of subsequent film deposition of the lead-free plating (in the second plating unit) has a large effect of inhibiting whisker formation.

Accordingly, the result has been obtained in which, when the first lead-free plating 8a (layer formed under changed conditions) formed in the first plating unit is formed on the lead side (inner side in the structure of FIG. 4), a current at a density higher than 20 A/dm² is applied, and then a current at a density lower than the foregoing current density in the first plating unit is applied in the second plating unit to form the second lead-free plating 8b on the surface side, the decrease ratio of the length of whisker is high (% with a negative sign (−) is high), and whisker is less likely to be formed.

A description will be given of the case where, based on the result of FIG. 17, such a first lead-free plating 8a (layer formed under changed conditions) as shown in FIG. 4 is formed on the lead side (inner side) by applying the first current density at a density higher than 20 A/dm² in the first plating unit in which the plating process is performed first, and then the second lead-free plating 8b is formed on the surface side as the layer over the first lead-free plating 8a by applying the second current density at a density lower than the density of the foregoing first current density in the second plating unit.

First, the resin molding is completed, and the matrix frames 2 formed with the molded bodies 3 covering the semiconductor chips 4 are prepared and, in the plating apparatus 6 of FIG. 13, each of the matrix frames 2 is supplied from the loader 6a to the electrolytic deburring unit 6b along the frame transportation direction 10.

Then, in the electrolytic deburring unit 6b, a thin mold bun attached onto the outer lead is lifted up using an alkaline solution, as shown in FIG. 16.

Thereafter, the matrix frame 2 is transported to the hydraulic deburring unit 6c, where the foregoing thin mold bun lifted over the matrix frame 2 is washed away with water.

Then, the matrix frame 2 is transported to the chemical polishing unit 6d, where the matrix frame 2 is subjected to chemical polishing. That is, the surface oxide film of the matrix frame 2 is removed, and surface activation is achieved. Note that, in the case where the raw material of the matrix frame 2 is an iron-nickel alloy, the surface oxide film is removed using a sulfuric acid, and the surface activation is performed using a nitric acid.

In the case where the raw material of the matrix frame 2 is a copper alloy, the removal of the surface oxide film and the surface activation are performed using a sulfuric acid.

Thereafter, the matrix frame 2 is transported to the acid activation unit 6e, where the acid activation of the matrix frame 2 is performed. That is, after the chemical polishing described above and prior to the plating formation step, the matrix frame 2 is cleaned with the same acid as that used in forming the first lead-free plating solution. An example of the acid used in the acid activation is a methanesulfonic acid, as shown in FIG. 16. The methanesulfonic acid is the same acid as that used in forming the first lead-free plating solution. By preliminarily cleaning the matrix frame 2 prior to the formation of the plating with the methanesulfonic acid, it is possible to provide the matrix frame 2 with affinity with the first lead-free plating solution prior to the formation of the first lead-free plating 8a, and form the uniformly thick first lead-free plating 8a in forming the plating.

In the acid activation step, the removal of the surface oxide film of the matrix frame 2 is removed using an alkyl sulfonic acid.

Thereafter, the matrix frame 2 is transported to the plating formation unit 6f, where the lead-free platings are formed. Here, in the first plating unit, the first current density is applied with the matrix frame 2 being dipped in the first lead-free plating solution to perform a first lead-free plating process with respect to the plurality of outer leads 2b. Then, in the second plating unit, the second current density at a density different from that of the foregoing first-current density is applied with the matrix frame 2 being dipped in the second lead-free plating solution having a composition of the same system as that of the composition of the first lead-free plating solution to perform a second lead-free plating process with respect to the plurality of outer leads 2b.

In Embodiment 1, such a first lead-free plating 8a (layer formed under changed conditions) as shown in FIG. 4 is formed on the lead side (inner side), and then the second lead-free plating 8b is formed on the surface side as the layer over the first lead-free plating 8a.

In the plating formation unit 6f of the plating apparatus 6 shown in FIG. 13, the one plating vessel 6g is provided, and the five stages (first and second plating units) are placed in the plating vessel 6g. Accordingly, the first lead-free plating solution used in the first plating unit and the second lead-free plating solution used in the second plating unit are the same plating solution.

Note that the five stages includes the first stage 6h disposed as the first plating unit for first forming the first lead-free plating 8a, and the second, third, fourth, and fifth stages 6j, 6m, 6p, and 6r each disposed as the second plating unit for subsequently forming the second lead-free plating 8b.

Thus, in the plating apparatus 6, the same lead-free plating solution is used in each of the first and second plating units. Therefore, it is possible to reduce apparatus cost.

To the first, second, third, fourth, and fifth stages 6h, 6j, 6m, 6p, and 6r, the first, second, third, fourth, and fifth rectifiers 6i, 6k, 6n, 6q, and 6s are electrically coupled, respectively. In other words, the rectifiers independent of each other are electrically coupled to the respective stages to provide a control structure which allows independent application of currents at densities different from one stage to another.

Note that, based on the result shown in FIG. 17, the first lead-free plating 8a (layer formed under changed conditions) is formed first on the lead side (inner side) of the outer plating 8 by applying the first current density at a density higher than 20 A/dm² from the first rectifier 6i at the first stage (in the first plating unit) 6h, and then the second lead-free plating 8b is formed on the surface side as the layer over the first lead-free plating 8a by applying the second current density at a density lower than that of the foregoing first current density in the second plating unit. That is, in the second plating unit, the second lead-free plating 8b is formed by applying the second current density at the density lower than that of the first current density applied in the first plating unit.

For example, in the plating vessel 6g, the first lead-free plating 8a (layer formed under changed conditions) is formed on the lead side (inner side) of the outer plating 8 under 30 A/dm² and 10-second conditions at the first stage (in the first plating unit) 6h, as shown in FIG. 4. Then, the second lead-free plating 8b is formed over the first lead-free plating 8a on the surface side under 20 A/dm² and 10-second conditions at each of the second stage (second plating unit) 6j to the fifth stage (second plating unit) 6r. Here, the 20 A/dm² and 10-second conditions are standard conditions in the formation of the lead-free platings. In this case, the formation of the first lead-free plating 8a as the layer formed under changed conditions is performed first with the high current density, and completed in a shorter period of time (10 seconds), and the second lead-free plating 8b is subsequently formed elaborately with the standard current density (20 A/dm²) in a longer period of time (4 cycles of 10 seconds).

By performing the plating process for 10 seconds at each of the first to fifth stages, the lead-free plating can be formed to a thickness of about 2 μm at each of the stages. That is, as shown in FIG. 4, the first lead-free plating 8a (layer formed under changed conditions) is formed to a thickness of 2 μm on the lead side (inner side) of the outer plating 8, and the second lead-free plating 8b is formed to a thickness of 8 μm in the layer thereover so that the outer plating 8 including the lead-free platings and having a total thickness of 10 μm is formed.

By thus forming the lead-free platings under two types of conditions in the first plating unit and in the second plating unit, the interface 8c can be formed between the first lead-free plating 8a and the second lead-free plating 8b over the outer lead 2b.

Note that, as shown in FIG. 16, the lead-free plating solution used in the plating formation unit 6f contains a methanesulfonic acid or an alkyl sulfonic acid as the acid component thereof, and a tin component is obtained by dissolving tin in the acid component. In addition, a surface active agent or the like is used as an additive.

In the case of forming the outer plating 8 having the structure shown in FIG. 5, the second lead-free plating 8b is formed to a thickness of 4 μm under, e.g., 20 A/dm² and 10-second conditions at each of the first and second stages 6h and 6j serving as the first plating unit. Then, at the third stage 6m serving as the second plating unit, the first lead-free plating 8a (layer formed under changed conditions) is formed to a thickness of 2 μm under, e.g., 30 A/dm² and 10-second conditions. Further, the second lead-free plating 8b is formed to a thickness of 4 μm under, e.g., 20 A/dm² and 10-second conditions at each of the fourth and fifth stages 6p and 6r serving as the third plating unit. In this manner, it is possible to form the outer plating 8 having a structure in which the first lead-free plating 8a is interposed between the second lead-free platings 8b in the thickness direction of the outer plating 8. In this structure also, the interface 8c can be formed between the first lead-free plating 8a and the second lead-free plating 8b.

In the case of forming the outer plating 8 having the structure shown in FIG. 6, the second lead-free plating 8b is formed to a thickness of 8 μm under, e.g., 20 A/dm² and 10-second conditions at each of the first to fourth stages 6h to 6p serving as the first plating unit. Then, at the fifth stage 6r serving as the second plating unit, the first lead-free plating 8a (layer formed under changed conditions) is formed to a thickness of 2 μm under, e.g., 30 A/dm² and 10-second conditions. In this manner, it is possible to form the outer plating 8 having a structure in which the first lead-free plating 8a is disposed on the surface side of the outer plating 8. In this structure also, the interface 8c can be formed between the first lead-free plating 8a and the second lead-free plating 8b.

After the lead-free plating is formed, the matrix frame 2 is transported to the water cleaning unit 6t, and cleaned with water therein. In the water cleaning unit 6t, the matrix frame 2 is cleaned first using pure water, as shown in FIG. 16. Then, the matrix frame 2 is ultrasonically cleaned similarly using pure water.

After water cleaning, the matrix frame 2 is transported to the drying unit 6u, and dried.

Thereafter, the matrix frame 2 is retrieved with the unloader 6v, whereby the plating formation step is completed.

After the completion of the plating formation step, the cutting/forming shown in Step S6 of FIG. 7 is performed. Here, the matrix frame 2 is cut to be singulated on a per package basis. At that time, as shown in FIG. 12, each of the plurality of outer leads 2b protruding from the molded body 3 is formed into a gull-wing shape by bending, whereby the assembly of the QFP 1 is completed.

In accordance with the method of manufacturing the semiconductor device according to Embodiment 1, the outer plating 8 over each of the outer leads 2b can be formed of the first lead-free plating 8a and the second lead-free plating 8b.

As a result, in the outer plating 8, the interface 8c is formed on the boundary between the first lead-free plating 8a and the second lead-free plating 8b. That is, by using currents at different densities (different plating conditions) to form the first lead-free plating 8a and the second lead-free plating 8b, the lead-free plating film including two layers having different physical properties is formed in the outer plating 8, and the interface 8c is formed therein.

Since the interface 8c is thus formed between the first lead-free plating 8a and the second lead-free plating 8b in the outer plating 8, even when a stress occurs between the outer lead 2b and the outer plating 8 in a temperature cycle test, the propagation of the stress can be reduced using the interface 8c formed in the outer plating 8.

As a result, it is possible to reduce the potential of whisker formation, and achieve an improvement in resistance to whisker formation.

### Embodiment 2

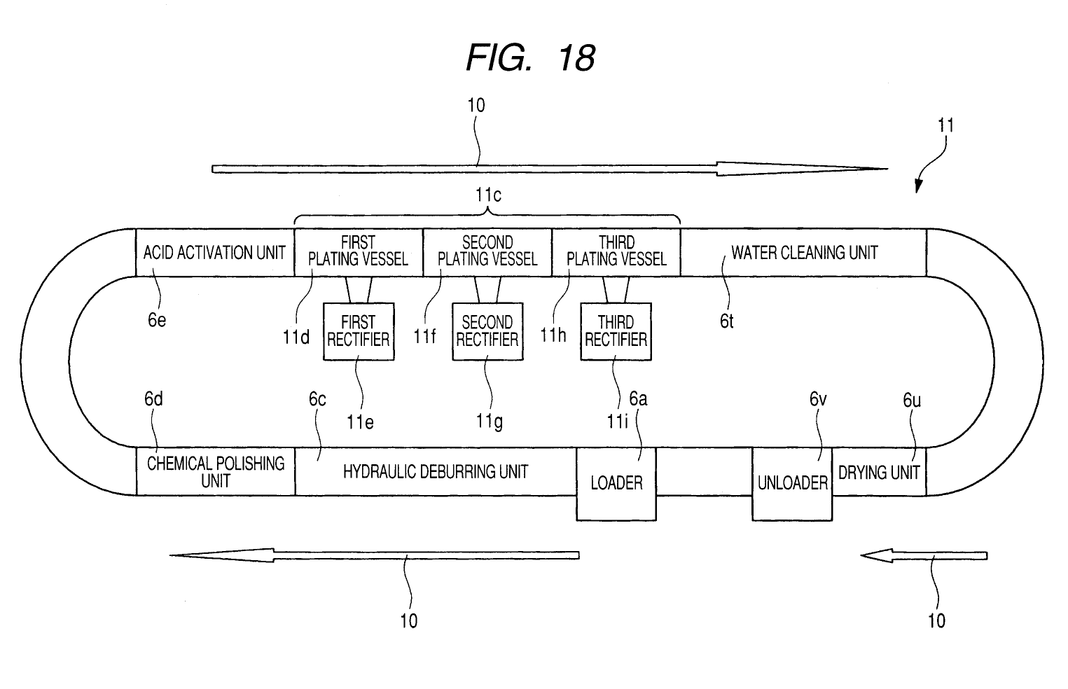

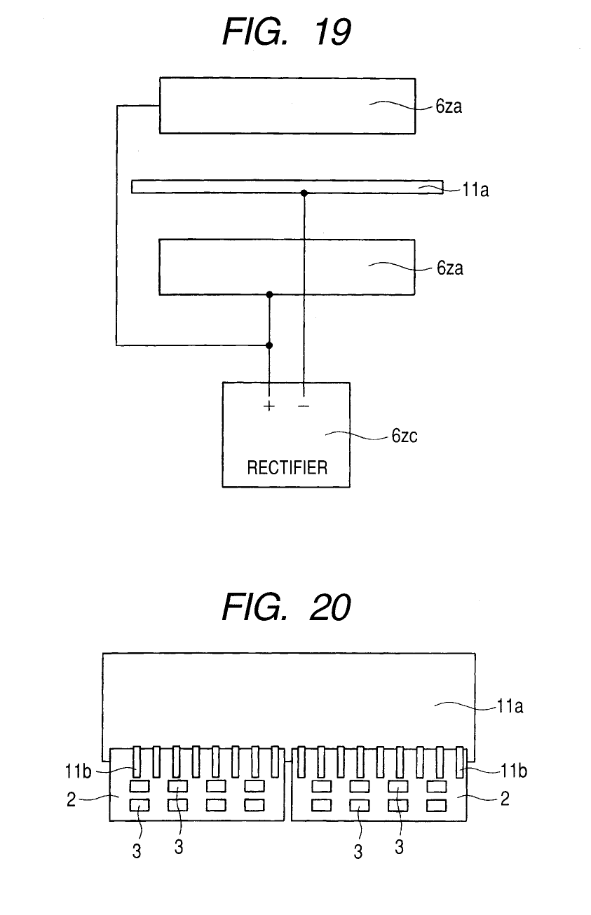

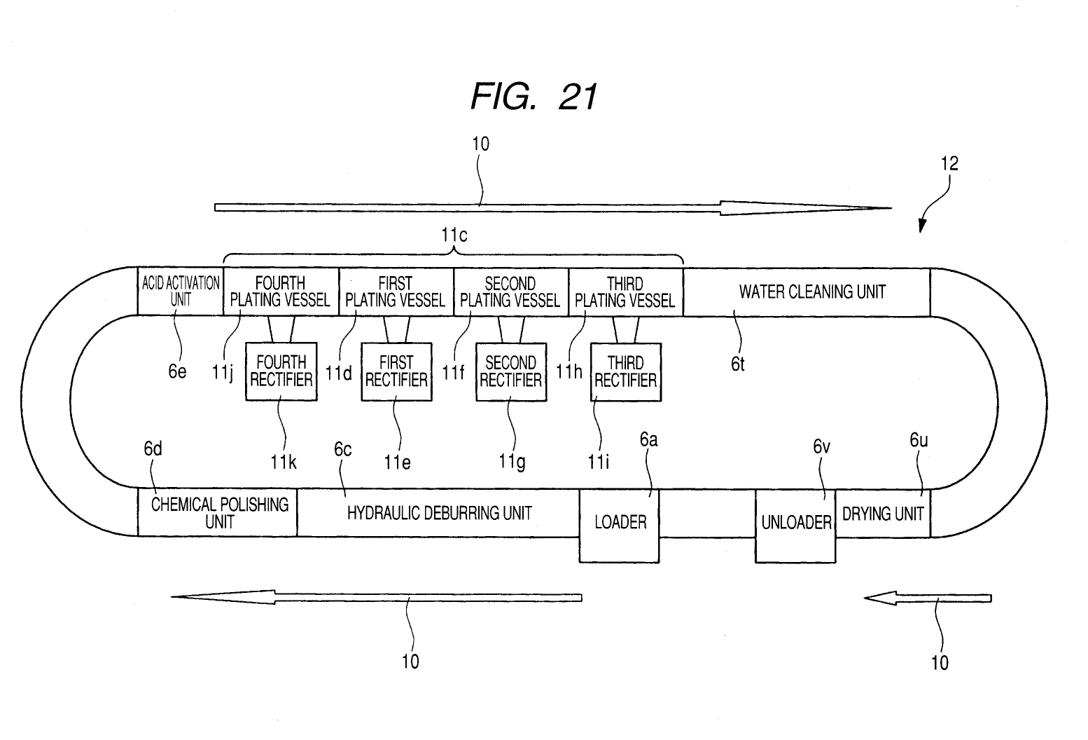

FIG. 18 is a block structural view showing an example of a structure of a plating apparatus used in a lead-free plating formation step in the assembly of a semiconductor device according to Embodiment 2 of the present invention. FIG. 19 is a schematic view showing an example of a power supply method in the plating apparatus shown in FIG. 18. FIG. 20 is a schematic structural view showing an example of a structure of a transport belt used in the power supply method shown in FIG. 19. FIG. 21 is a block structural view showing a structure of a variation of the plating apparatus used in the lead-free plating formation step in the assembly of the semiconductor device according to Embodiment 2.

In Embodiment 2, the transportation of the frame in a plating apparatus 11 used in the lead-free plating formation step shown in FIG. 18 is performed according to a system in which the frame 2 is transported round the plating apparatus 11 while being held by the transport belt 11a shown in FIG. 20. In addition, a plurality of plating vessels are provided in a plating formation unit 11c to be disposed on a per processing unit basis.

That is, in the plating apparatus 11, each of the matrix frames 2 formed with the molded bodies 3 as shown in FIG. 20 is transported while being held by the holding portion 11b of the transport belt 11a, subjected to a predetermined process in each of the processing units while remaining held by the holding portion 11b, and transported from the loader 6a to the unloader 6v, as shown in FIG. 18. The transport belt 11a is made of a conductive member of, e.g., stainless steel or the like, and electrically coupled to the rectifier 6zc, as shown in FIG. 19, to supply power to the matrix frame 2 via the anodes 6za and the transport belt 11a in the plating formation unit 11c.

Note that, in the plating apparatus 11, the matrix frame 2 being held by the holding portion 11b of the transport belt 11a is transported from the loader 6a, and subjected to the same process as performed in the plating apparatus 6 according to Embodiment 1 in each of the hydraulic deburring unit 6c, the chemical polishing unit 6d, and the acid activation unit 6e. Then, the matrix frame 2 is transported to the plating formation unit 11c.

In the plating formation unit 11c, the first plating unit and the second plating unit are placed in different plating vessels.

That is, in the plating formation unit 11c, a first plating vessel (first plating unit) 11d, a second plating vessel (second plating unit) 11f, and a third plating vessel (second plating unit) 11h are provided discretely, and electrically coupled to a first rectifier 11e, a second rectifier 11g, and a third rectifier 11i, respectively.

Therefore, by, e.g., using conditions for forming the first lead-free plating 8a (layer formed under changed conditions) as conditions for plating formation in any of the three plating vessels, it is possible to form the outer plating 8 of the first lead-free plating 8a and the second lead-free plating 8b in the same manner as in Embodiment 1.

In this manner, in the plating apparatus 11 according to Embodiment 2 also, the interface 8c can be formed in the outer plating 8 in the same manner as in Embodiment 1. Even when a stress occurs between the outer lead 2b and the outer plating 8 in a temperature cycle test, the propagation of the stress can be reduced using the interface 8c formed in the outer plating 8.

As a result, it is possible to reduce the potential of whisker formation, and achieve an improvement in resistance to whisker formation.

Next, a description will be given of a plating apparatus 12 according to a variation of Embodiment 2 shown in FIG. 21. In the plating apparatus 12, the first plating vessel 11d, the second plating vessel 11f, and the third plating vessel 11h are provided discretely in the plating formation unit 11c and, in addition, a fourth plating vessel 11j as a vessel exclusively for forming the first lead-free plating 8a (layer formed under changed conditions) is further provided. The fourth plating vessel 11j is also electrically coupled individually to a fourth rectifier 11k. From the plating apparatus 12 thus provided with the plating vessel (fourth plating vessel 11j) exclusively for forming the first lead-free plating 8a (layer formed under changed conditions) also, the same effects as obtained from the plating apparatus 6 according to Embodiment 1 and the plating apparatus 11 according to Embodiment 2 can be obtained.

While the invention achieved by the present inventors has been specifically described heretofore based on the embodiments of the present invention, it will be appreciated that the present invention is not limited to the foregoing embodiments thereof, and various changes and modifications can be made in the invention within the scope not departing from the gist thereof.

For example, in the lead-free plating formation step, the processing unit for forming the first lead-free plating 8a (layer formed under changed conditions) may be either the first plating unit or the second plating unit. The categorization of the first plating unit and the second plating unit is for showing the order in which plating processes are performed. As long as plating formation is performed in the first plating unit, and then plating formation is performed in the second plating unit, the formation of the first lead-free plating 8a and the second lead-free plating 8b may be performed in either of the first and second plating units.

As the conditions for forming the first lead-free plating 8a and the second lead-free plating 8b, 30 A/dm² and 10-second conditions, 20 A/dm² and 10-second conditions, and the like have been described as examples. However, any combinational conditions may be used as long as it is determined based on the result shown in FIG. 17 that the decrease ratio of the length of whisker is high (% with a negative sign (−) is high), whisker is less likely to be formed, and the interface 8c is formed in the outer plating 8, such as in the case where the current density is increased or decreased or a film deposition speed when the plating process is performed first is decreased, where a film deposition speed when the plating process is finally performed is increased or decreased, or where a film deposition speed at the middle is decreased.

The present invention is suitable for the assembly of an electronic device in which a lead-free plating is formed.

What is claimed is:

1. A method of manufacturing a semiconductor device, comprising the steps of:
(a) preparing a lead frame formed with a molded body covering a semiconductor chip; and
(b) placing the lead frame in a plating apparatus including a first plating unit and a second plating unit which are individually coupled to different rectifiers, and performing a lead-free plating process with respect to a plurality of outer leads exposed from the molded body of the lead frame,
wherein, in the step (b), a first current density is applied in the first plating unit with the lead frame being dipped in a first lead-free plating solution to perform a first lead-free plating process with respect to the outer leads, and then a second current density at a density different from a density of the first current density is applied in the second plating unit with the lead frame being dipped in a second lead-free plating solution having the same composition as that of the first lead-free plating solution to perform a second lead-free plating process with respect to the outer leads.

2. The method of manufacturing the semiconductor device according to claim 1,
wherein, prior to the step (b), the lead frame is subjected to chemical polishing.

3. The method of manufacturing the semiconductor device according to claim 2,
wherein, after the chemical polishing and prior to the step (b), the lead frame is cleaned with the same acid as an acid used when the first lead-free plating solution is formed.

4. The method of manufacturing the semiconductor device according to claim 3,
wherein the first lead-free plating solution used in the first plating unit and the second lead-free plating solution used in the second plating unit are the same.

5. The method of manufacturing the semiconductor device according to claim 1,
wherein the density of the second current density applied in the second plating unit is lower than the density of the first current density applied in the first plating unit.

6. The method of manufacturing the semiconductor device according to claim 1,
wherein the first plating unit and the second plating unit are placed in the same and one plating vessel.

7. The method of manufacturing the semiconductor device according to claim 1,
wherein the first plating unit and the second plating unit are placed in different plating vessels.

8. The method of manufacturing the semiconductor device according to claim 1,
wherein the lead frame is made of an iron-nickel alloy.

9. The method of manufacturing the semiconductor device according to claim 1,
wherein a lead-free plating is a tin-copper plating.

10. The method of manufacturing the semiconductor device according to claim 1,
wherein a silver plating is formed over a wire bonded portion of each of the inner leads provided in the lead frame.

11. A method of manufacturing a semiconductor device, comprising the steps of:
(a) preparing a thin-plate-like lead frame having a die pad, a plurality of inner leads arranged around the die pad, and a plurality of outer leads integrally coupled to the respective inner leads;
(b) mounting a semiconductor chip over the die pad;
(c) electrically coupling a plurality of electrode pads of the semiconductor chip to the respective inner leads with wires;
(d) molding the semiconductor chip, the inner leads, and the wires into a molded body;
(e) placing the lead frame formed with the molded body in a plating apparatus including a first plating unit and a second plating unit which are individually coupled to different rectifiers, and performing a lead-free plating process with respect to the outer leads exposed from the molded body; and
(f) cutting/separating the outer leads from the lead frame to perform singulation,
wherein, in the step (e), a first current density is applied in the first plating unit with the lead frame being dipped in a first lead-free plating solution to perform a first lead-free plating process with respect to the outer leads, and then a second current density at a density different from a density of the first current density is applied in the second plating unit with the lead frame being dipped in a second lead-free plating solution having the same composition as that of the first lead-free plating solution to perform a second lead-free plating process with respect to the outer leads.
